(19) United States
(12) Patent Application Publication
(10) Pub. No.: US 2008/0205219 A1
(43) Pub. Date: Aug. 28, 2008

(54) JITTER MEASURING APPARATUS AND METHOD, SIGNAL PERIOD MEASURING APPARATUS AND METHOD, AND OPTICAL DISK PLAYER

(75) Inventors: Wook-yeon Hwang, Seoul (KR); Hyun-soo Park, Seoul (KR); In-oh Hwang, Seongnam-si (KR); Kyung-geun Lee, Seongnam-si (KR)

Correspondence Address: STEIN, MCEWEN & BUI, LLP, 1400 EYE STREET, NW, SUITE 300, WASHINGTON, DC, 20005, US

(73) Assignee: Samsung Electronics Co., Ltd., Suwon-si (KR)

(21) Appl. No.: 12/014,385

(22) Filed: Jan. 15, 2008

(30) Foreign Application Priority Data
Feb. 22, 2007 (KR) 2007-18090
Mar. 2, 2007 (KR) 2007-21148

(51) Int. Cl. G11B 20/18; G01R 29/26

(52) U.S. Cl. 369/53.1; 702/69

(57) ABSTRACT

An apparatus to measure jitter of a signal read from an optical disk includes a binarization unit to binarize an input signal to generate a binary signal, an ideal signal generator to generate a noise-free ideal signal based on channel characteristics of the optical disk, and a jitter measurement unit to measure jitter of the input signal based on the binary signal and the ideal signal.

### CROSS-REFERENCE TO RELATED APPLICATIONS

This application claims the benefit of Korean Application Nos. 2007-18090, filed Feb. 22, 2007, and 2007-21148, filed Mar. 2, 2007, in the Korean Intellectual Property Office, the disclosure of which is incorporated herein by reference.

### BACKGROUND OF THE INVENTION

1. Field of the Invention

Aspects of the present invention relate to a jitter measuring apparatus and method, a signal period measuring apparatus and method, and an optical disk player.

2. Description of the Related Art

An optical disk player, i.e., an optical disk recording and reproducing apparatus, records a binary signal on the surface of an optical disk. When the recorded binary signal is reproduced, the optical disk player irradiates a laser beam onto the surface of the optical disk and reads a signal reflected from the surface of the optical disk. The signal read from the surface of the optical disk is an RF (Radio Frequency) signal. Even when a binary signal is recorded on the surface of the optical disk, an RF signal read from the surface of the optical disk has properties of an analog signal due to the characteristics of the optical disk and optical characteristics of the optical disk player. Accordingly, a binarization process is used to convert the RF signal having the properties of an analog signal into the binary signal.

FIG. 1 illustrates a circuit configuration used to perform a conventional binarization process. Referring to FIG. 1, the binarization process is carried out using a comparator 110 and a low pass filter 120. The comparator 110 compares an input RF signal to a slicing level. The input RF signal is read from an optical disk, such as a digital versatile disc (DVD), a high-density DVD (HD-DVD), a Blu-ray DVD (BD), etc. The output signal of the comparator 110 is transmitted to the low pass filter 120. The low pass filter 120 low-pass-filters the output signal of the comparator 110. The output signal of the low pass filter is transmitted as the slicing level of the comparator 110.

Conventional optical disk players convert an RF signal read from an optical disk into a binary signal through the above-described binarization process and apply the binary signal to a phase locked loop to generate a system clock signal. Then, the conventional optical disk player reproduces data from the optical disk using the binary signal and the system clock signal. A slight phase difference may occur between the RF signal and the system clock signal. This slight phase difference is referred to as jitter.

FIGS. 2A and 2B illustrate jitter generated between an offset-removed RF signal 220 and a system clock signal 210 when a falling edge of the system clock signal 210 occurs after and before the zero crossing point of the RF signal 220, respectively. In an ideal case, an edge of the system clock signal 210 corresponds to the zero crossing point of the RF signal 220. However, in practice, an edge of the system clock signal 210 does not correspond to the zero cross point of the RF signal 220 and a slight time difference, that is, jitter, is generated between the system clock signal 210 and the RF signal 220.

The jitter between the RF signal 220 and the system clock signal 210 is used to evaluate the quality of the RF signal 220. That is, in an ideal case, the zero crossing point of the RF signal 220 precisely corresponds to an edge of the system clock signal 210, and thus jitter is barely, if at all, capable of being measured. However, when the RF signal 220 has noise or is generated in an abnormal state, the zero crossing point of the RF signal 220 does not correspond to an edge of the system clock signal 210, resulting in jitter which is more easily measurable. Accordingly, the quality of the RF signal 220 is confirmed based on the measured jitter.

However, the magnitude of the RF signal 220 corresponding to a binary signal with a short T (T is a distance of 1 pit on the recording surface of the optical disk) decreases as the recording densities of optical disks increase. Accordingly, even when the RF signal 220 corresponding to the binary signal with a short T has a small amount of noise, a relatively large signal distortion is generated or located near the zero crossing point, and thus jitter may be erroneously measured. Therefore, it is difficult to correctly evaluate the quality of the RF 220 signal using jitter which is measured based on a difference between the RF signal 220 and the system clock signal 12 in the case of high-density optical disks.

### SUMMARY OF THE INVENTION

Aspects of the present invention provide an apparatus and method to accurately measuring jitter of a signal to evaluate the quality of the signal.

Aspects of the present invention also provide an apparatus and method to measure the period of a signal to evaluate the quality of the signal.

According to an aspect of the present invention, an apparatus to measure jitter of an input signal read from an optical disk includes a binarization unit to binarize an input signal to generate a binary signal; an ideal signal generator to generate a noise-free ideal signal based on the channel characteristics of the optical disk; and a jitter measurement unit to measure the jitter of the input signal based on the binary signal and the noise-free ideal signal.

According to an aspect of the present invention, the ideal signal generator generates the noise-free ideal signal by filtering the binary signal using the channel characteristics of the optical disk.

According to an aspect of the present invention, the ideal signal generator selects a level representing the channel characteristics of the optical disk based on a plurality of predetermined binary signals and outputs a signal corresponding to the selected level as the noise-free ideal signal.

According to an aspect of the present invention, the apparatus further includes a level detector to detect levels of the input signal based on the binary signal.

According to an aspect of the present invention, the ideal signal generator selects one of the levels detected by the level detector based on predetermined binary signals and outputs a signal corresponding to the selected level as the noise-free ideal signal.

According to an aspect of the present invention, the level detector obtains means of the input signal and previous input signals to detect the levels of the input signal.

According to an aspect of the present invention, the level detector includes an input signal splitter to split the input signal into the levels using the binary signal, and a filtering unit to obtain means of the respective levels.

According to an aspect of the present invention, the input signal splitter includes at least one delay unit to delay the input signal to synchronize the input signal with the binary signal.

According to an aspect of the present invention, the jitter measurement unit calculates a time axis of the input signal with respect to the noise-free ideal signal at a moment when the binary signal changes and outputs the time axis error as the jitter of the input signal.

According to an aspect of the present invention, the time axis error corresponds to a value obtained by subtracting a mean of the input signal at the moment when the binary signal changes from a mean of the noise-free ideal signal at the moment when the binary signal changes and dividing the subtraction result by a variation of the ideal signal at the moment when the binary signal changes.

According to another aspect of the present invention, a method of measuring jitter of an input signal read from an optical disk includes binarizing the input signal to generate a binary signal, generating a noise-free ideal signal based on channel characteristics of the optical disk, and measuring jitter of the input signal based on the binary signal and the noise-free ideal signal.

According to another aspect of the present invention, the generating of the noise-free ideal signal includes generating the noise-free ideal signal by filtering the binary signal using the channel characteristics of the optical disk.

According to another aspect of the present invention, the generating of the noise-free ideal signal includes selecting a level representing the channel characteristics of the optical disk based on a plurality of predetermined binary signals and outputting a signal corresponding to the selected level as the noise-free ideal signal.

According to another aspect of the present invention, the method further includes detecting levels of the input signal based on the binary signal, and the generating of the ideal signal includes selecting one of the levels detected by the level detector based on predetermined binary signals and outputting a signal corresponding to the selected level as the noise-free ideal signal.

According to another aspect of the present invention, the detecting of the levels of the input signal includes obtaining means of the input signal and previous input signals to detect the levels of the input signal.

According to another aspect of the present invention, the detecting of the levels of the input signal includes splitting the input signal into a plurality of levels using the binary signal, and obtaining means of the respective levels.

According to another aspect of the present invention, the splitting of the input signal includes delaying the input signal to synchronize the input signal with the binary signal before the input signal is split into the levels.

According to another aspect of the present invention, the measuring of the jitter includes calculating a time axis error of the input signal with respect to the noise-free ideal signal at a moment when the binary signal changes and outputting the time axis error as the jitter of the input signal.

According to another aspect of the present invention, the time axis error corresponds to a value obtained by subtracting a mean of the input signal at the moment when the binary signal changes from a mean of the noise-free ideal signal at the moment when the binary signal changes and dividing the subtraction result by a variation of the noise-free ideal signal at the moment when the binary signal changes.

According to another aspect of the present invention, an optical disk player includes an equalizer to equalize a signal picked up from an optical disk, a jitter measuring device to receive the signal transmitted from the equalizer and to measure jitter of the signal; and a signal processor to evaluate a quality of the signal using the measured jitter, wherein the jitter measuring device includes a binarization unit to binarize an input signal to generate a binary signal, an ideal signal generator to generate a noise-free ideal signal based on channel characteristics of the optical disk, and a jitter measurement unit to measure the jitter of the input signal based on the binary signal and the noise-free ideal signal.

According to another aspect of the present invention, a computer readable recording medium encoded with a computer-readable program with processing instructions for executing a jitter measuring method includes binarizing an input signal to generate a binary signal, generating a noise-free ideal signal based on channel characteristics of an optical disk from which the input signal is read, and measuring the jitter of the input signal based on the binary signal and the noise-free ideal signal.

According to another aspect of the present invention, an apparatus to measure a period of an input signal picked up from an optical disk includes a binarization unit to binarize an input signal to generate a binary signal, an ideal signal generator to generate a noise-free ideal signal based on channel characteristics of the optical disk, and a period measurement unit to measure the period of the input signal based on the binary signal and the ideal signal.

According to another aspect of the present invention, the ideal signal generator generates the noise-free ideal signal by filtering the binary signal using the channel characteristics of the optical disk.

According to another aspect of the present invention, the ideal signal generator selects a level to represent the channel characteristics of the optical disk based on a plurality of predetermined binary signals and outputs a signal corresponding to the selected level as the noise-free ideal signal.

According to another aspect of the present invention, the apparatus further includes a level detector to detect levels of the input signal based on the binary signal, and the ideal signal generator selects one of the levels detected by the level detector based on predetermined binary signals and outputs a signal corresponding to the selected level as the noise-free ideal signal.

According to another aspect of the present invention, the level detector obtains means of the input signal and previous input signals to detect the levels of the input signal.

According to another aspect of the present invention, the level detector includes an input signal splitter to split the input signal into a plurality of the levels using the binary signal, and a filtering unit to obtain means of the respective levels.

According to another aspect of the present invention, the input signal splitter includes at least one delay unit to delay the input signal to synchronize the input signal with the binary signal.

According to another aspect of the present invention, the period measurement unit includes an error calculator to calculate a time axis error of the input signal with respect to the noise-free ideal signal at a moment when the binary signal changes, and a period controller to add the time axis error to the period of the input signal right before the binary signal changes and to subtract the time axis error from the period of the input signal right after the binary signal changes to control the period of the input signal.

According to another aspect of the present invention, the error calculator subtracts a mean of the input signal at the moment when the binary signal changes from a mean of the ideal signal at the moment when the binary signal changes and divides a subtraction result by a variation of the noise-free ideal signal at the moment when the binary signal changes to calculate the time axis error.

According to another aspect of the present invention, a method of measuring the period of an input signal read from an optical disk includes binarizing the input signal to generate a binary signal, generating a noise-free ideal signal based on channel characteristics of the optical disk, and measuring the period of the input signal based on the binary signal and the noise-free ideal signal.

According to another aspect of the present invention, the generating of the noise-free ideal signal including generating the ideal signal by filtering the binary signal using the channel characteristics of the optical disk.

According to another aspect of the present invention, the generating of the ideal signal includes selecting a level representing the channel characteristics of the optical disk based on a plurality of predetermined binary signals and outputting a signal corresponding to the selected level as the ideal signal.

According to another aspect of the present invention, the method further includes detecting levels of the input signal based on the binary signal, and the generating of the ideal signal includes selecting one of the levels detected by the level detector based on predetermined binary signals and outputting a signal corresponding to the selected level as the noise-free ideal signal.

According to another aspect of the present invention, the detecting of the levels of the input signal includes obtaining means of the input signal and previous input signals to detect the levels of the input signal.

According to another aspect of the present invention, the detecting of the levels of the input signal includes splitting the input signal into the levels using the binary signal, and obtaining means of the respective levels.

According to another aspect of the present invention, the splitting of the input signal includes delaying the input signal to synchronize the input signal with the binary signal before the input signal is split into the levels.

According to another aspect of the present invention, the measuring of the period includes calculating a time axis error of the input signal with respect to the noise-free ideal signal at a moment when the binary signal changes, adding the time axis error to the period of the input signal right before the moment when the binary signal changes, and subtracting the time axis error from the period of the input signal right after the moment when the binary signal changes to control the period of the input signal.

According to another aspect of the present invention, the calculating of the time axis error includes subtracting a mean of the input signal at the moment when the binary signal changes from a mean of the noise-free ideal signal and dividing a result of the subtracting by a variation of the noise-free ideal signal at the moment when the binary signal changes to calculate the time axis error.

According to another aspect of the present invention, an optical disk player includes an equalizer to equalize a signal picked up from an optical disk, a signal period measuring device to measure a period of the signal, and a signal processor to evaluate a quality of the signal using the measured period.

According to another aspect of the present invention, the signal period measuring device includes a binarization unit to binarize an input signal to generate a binary signal, an ideal signal generator to generate a noise-free ideal signal based on channel characteristics of the optical disk, and a period measurement unit to measure jitter of the input signal based on the binary signal and the ideal signal.

According to another aspect of the present invention, a computer readable recording medium is encoded with a computer-readable program with processing instructions for executing a signal period measuring method, the signal period measuring method including binarizing an input signal to generate a binary signal, generating a noise-free ideal signal based on channel characteristics of an optical disk from which the input signal is read; and measuring a period of the input signal based on the binary signal and the ideal signal.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 illustrates a circuit configuration to perform a conventional binarization process;

FIGS. 2A and 2B illustrate jitter generated between an offset-removed RF signal and a system clock signal when a falling edge of the system clock signal occurs after and before the zero crossing point of the RF signal, respectively;

FIG. 3 is a block diagram of a jitter measuring apparatus according to an embodiment of the present invention;

FIG. 4 is a block diagram illustrating a detailed configuration of the jitter measuring apparatus shown in FIG. 3;

FIG. 5 is a block diagram of a level detector according to an embodiment of the present invention;

FIG. 6 illustrates a hardware configuration of a PR(1,2,1) channel;

FIG. 7 is a graph illustrating a change of a binary signal of an input signal from −1 to 1;

FIGS. 8A and 8B illustrate a method of calculating a time axis error of an input signal according to an embodiment of the present invention;

FIG. 9 is a graph illustrating the frequency of a time axis error detected using the jitter measuring apparatus shown in FIG. 3;

FIG. 10 is a flow chart of a jitter measuring method according to an embodiment of the present invention;

FIG. 11 is a flow chart of a jitter measuring method according to another embodiment of the present invention;

FIG. 12 is a block diagram of an optical disk player according to an embodiment of the present invention;

FIG. 13 is a block diagram of a signal period measuring apparatus according to an embodiment of the present invention;

FIG. 14 is a block diagram illustrating a detailed configuration of the signal period measuring apparatus illustrated in FIG. 13;

FIG. 15 is a graph illustrating the relationship between a signal magnitude and a mark length detected using the signal period measuring apparatus shown in FIG. 13;

FIG. 16 is a flow chart of a signal period measuring method according to an embodiment of the present invention;

FIG. 17 is a flow chart of a signal period measuring method according to another embodiment of the present invention; and

FIG. 18 is a block diagram of an optical disk player according to another embodiment of the present invention.

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

FIG. 3 is a block diagram of a jitter measuring apparatus 300 according to an embodiment of the present invention. Referring to FIG. 3, the jitter measuring apparatus 300 includes a binarization unit 310, an ideal signal generator 320, and a jitter measurement unit 330. The jitter measuring apparatus 300 can be included in an optical disk player or can be manufactured and sold separately from the optical disk player. Furthermore, the optical disk player may be capable of reproducing data from an optical disk, or may alternatively be capable of both recording data to and reproducing data from the optical disk.

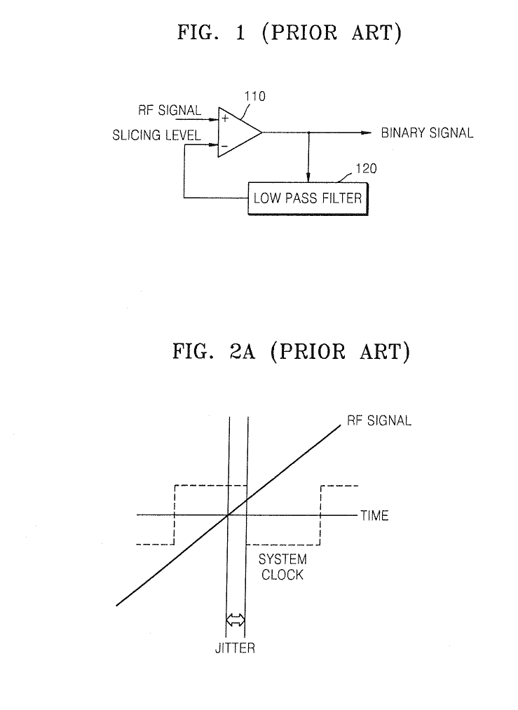

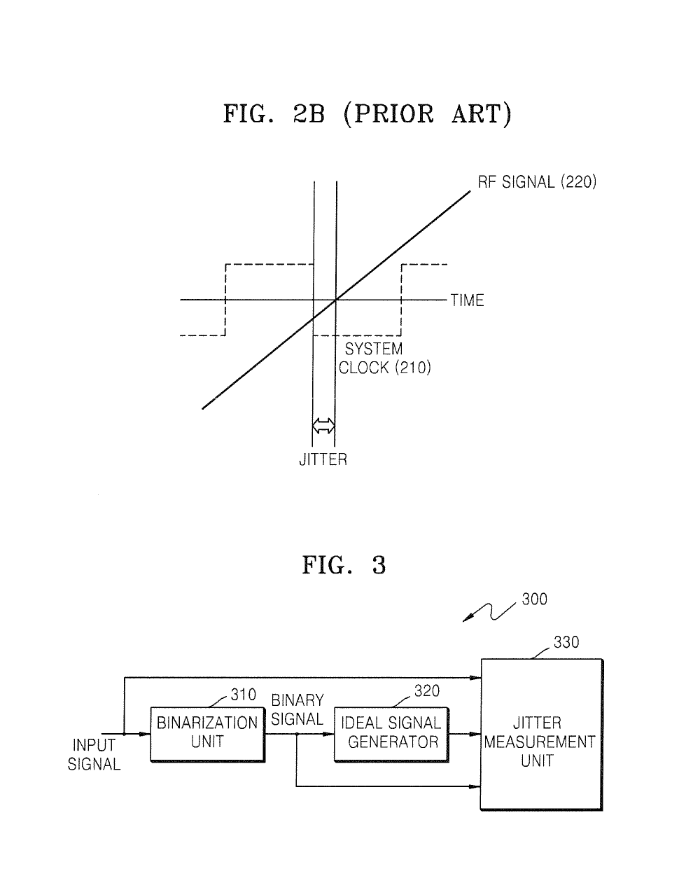

The binarization unit 310 converts an input RF signal into a binary signal. When a binary signal is recorded on the surface of an optical disk, an RF signal picked up from the optical disk has properties of an analog signal due to characteristics of the optical disk and characteristics of the optical disk player. Accordingly, the input RF signal is converted into the binary signal by the binarization unit 310. The binarization unit 310 can generate the binary signal using a slicing circuit and a known method, such as the method illustrated in FIG. 1 and described above. Furthermore, the binarization unit 310 can generate the binary signal through a method using a viterbi decoder, such as a partial response maximum likelihood (PRML) method. These various methods may be separately used or combined.

The ideal signal generator 320 receives the binary signal transmitted from the binarization unit 310 and generates a noise-free ideal signal based on the channel characteristics of an optical disk from which the input RF signal is read. According to an aspect of the present invention, the ideal signal is generated by filtering the binary signal using the channel characteristics of the optical disk. For example, when the binary signal input to the ideal signal generator 320 is x(n) and the channel characteristics of the optical disk are h(n), the ideal signal is obtained using the following equation:

y(n)=x(n)*h(n) [Equation 1]

Here, * represents a convolution operation and y(n) represents the ideal signal.

According to an aspect of the present invention, the ideal signal is generated using a level representing the characteristics of the input signal. Specifically, a level representing the channel characteristics of the optical disk is selected based on a plurality of predetermined binary signals. Once the level is selected, a signal corresponding to the selected level is output as the ideal signal. The predetermined binary signals are obtained by passing the binary signal input to the ideal signal generator 320 through a plurality of delay units and synchronizing the binary signals respectively output from the delay units. The level representing the channel characteristics of the optical disk is selected from signals which are obtained by multiplexing the binary signals. To achieve this, the input signal is divided into a plurality of levels.

The jitter measurement unit 330 accurately measures jitter of the input RF signal based on the binary signal output from the binarization unit 310 and the ideal signal output from the ideal signal generator 320.

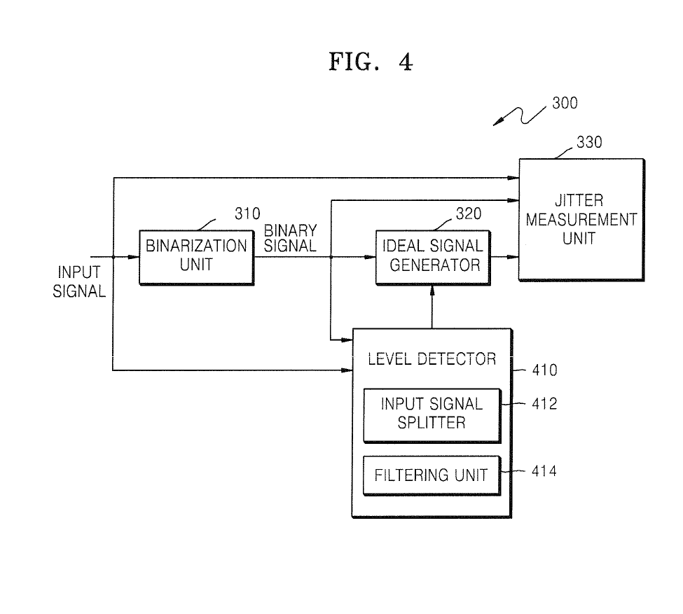

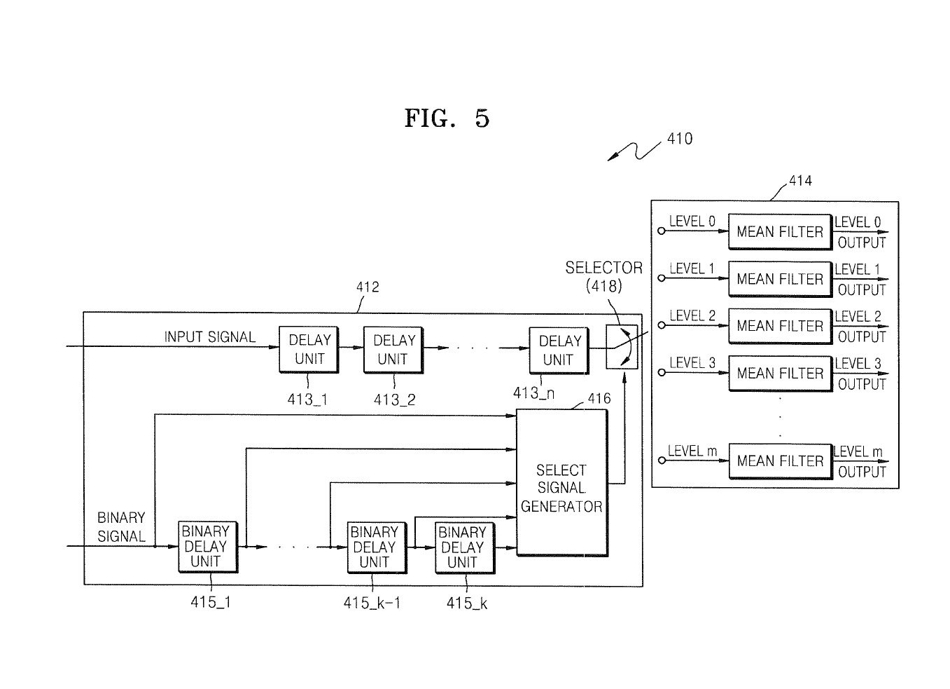

FIG. 4 is a block diagram illustrating a detailed configuration of the jitter measuring apparatus 300 shown in FIG. 3. Referring to FIG. 4, the jitter measuring apparatus 300 includes the binarization unit 310, the ideal signal generator 320, a level detector 410 and the jitter measurement unit 330. The level detector 410 includes an input signal splitter 412 and a filtering unit 414.

The binarization unit 310 binarizes an input signal read from the optical disk and outputs a binary signal according to the input signal. The ideal signal generator 320 receives the binary signal and generates a noise-free ideal signal based on the channel characteristics of an optical disk from which the input signal is picked up. The ideal signal generator 320 selects a level corresponding to the channel characteristics of the optical disk from a predetermined plurality of binary signals and outputs a signal having the selected level as the ideal signal. To achieve this, the input signal is divided into a plurality of levels, and values or signals respectively corresponding to the levels are set.

The level detector 410 detects the level of the input signal based on the binary signal. In detail, the input signal splitter 412 splits the input signal into a plurality of levels using the binary signal. The filtering unit 414 includes mean filters, i.e., average filters, and obtains means, i.e. averages, of the respective levels using the mean filters. A detailed configuration of the level detector 410 will be explained later with reference to FIG. 5.

The jitter measurement unit 330 accurately measures jitter of the input signal based on the binary signal and the ideal signal. The input signal is synchronized through a delay unit and then input to the jitter measurement unit 330. The quality of the input signal is accurately calculated when the jitter of the input signal is accurately measured. The jitter measurement unit 330 calculates a time axis error of the input signal with respect to the ideal signal at a time, or a moment, when the binary signal changes and outputs the calculated time axis error as a jitter. In detail, the jitter measurement unit 330 calculates the time axis error by subtracting a mean of the input signal at the moment when the binary signal changes from a mean of the ideal signal at the moment when the binary signal changes and dividing the subtraction result by a variation of the ideal signal at the moment when the binary signal changes.

FIG. 5 is a block diagram of the level detector 410 according to an embodiment of the present invention. The level detector 410 includes the input signal splitter 412 and the filtering unit 414. The input signal splitter 412 includes n delay units 413_1 through 413_{—}n which delay the input signal in order to synchronize the input signal and the binary signal with each other. The input signal splitter 412 further includes k binary delay units 415_1 through 415_{—}k which delay the binary signal, a select signal generator 416, and a selector 418. The select signal generator 416 combines binary signals input thereto and outputs a select signal. According to an aspect of the present invention, the select signal generator 416 generates one of the 2^{k+1} select signals because there are k binary delay units 415_1 through 415_{—}k. For example, the select signal generator 416 generates one of 2³ possible select signals when k is 2. The 2³ possible select signals include 000, 001, 010, 011, 100, 101, 110 and 111.

The selector 418 selects a level of the synchronized input signal based on the select signal output from the select signal generator 416. For example, the selector 418 outputs a level 0 as the level of the synchronized input signal when 000 is output as the select signal from the select signal generator 416, and outputs a level m as the level of the synchronized input signal when 111 is output as the select signal from the select signal generator 416. Using the above example, the level m corresponds to a level 7 because the selected signal generator 416 generates 2³ select signals, the first level is 0, and there are a total of 8 levels.

In this manner, the level (one of levels 0 through m) of the input signal corresponding to the binary signal is output from the input signal splitter 412. The level output from the input signal splitter 412 is considered as an estimated value of the ideal signal. The level output from the input signal splitter 412 is transmitted to the filtering unit 414.

The filtering unit 414 includes m+1 mean filters which are used to obtain means for the respective levels, and outputs the means as levels of the input signal. According to an aspect of the present invention, the mean filters obtain means of the levels input thereto for a long period. However, the mean filters may alternatively obtains means for a relatively shorter period of time. Additionally, the mean filters can be low pass filters, but are not limited to such, and may instead be other types of filters, such as high pass filters or band-pass filters. The means obtained by the mean filters are input to the ideal signal generator 320.

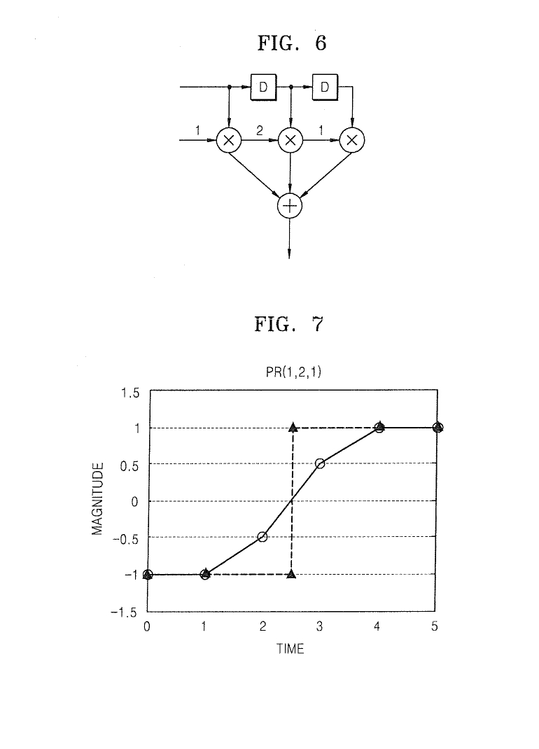

The principle of checking signal quality from an ideal input signal will be explained. First, a partial response (PR) channel will be described. A PR(1,2,1) channel obtains signals that have passed through digital filters respectively having filter coefficients 1, 2 and 1 when a binary signal is input. A hardware configuration of the PR(1,2,1) channel is illustrated in FIG. 6. When −1 or 1 is used as the input binary signal in order to make a DC value 0, 2³ input signal combinations are obtained because three binary signals construct a single output signal. This principle is represented by Table 1.

TABLE 1

| Number | Input | Output |
|---|---|---|
| 1 | −1 −1 −1 | −4 |
| 2 | −1 −1 +1 | −2 |
| 3 | −1 +1 −1 | 0 |
| 4 | −1 +1 +1 | +2 |
| 5 | +1 −1 −1 | −2 |
| 6 | +1 −1 +1 | 0 |
| 7 | +1 +1 −1 | +2 |
| 8 | +1 +1 +1 | +4 |

In Table 1, the third and sixth cases correspond to binary signals having 1T. In the case of a (BD) or an HD-DVD, a binary signal does not have 1T, and thus 0 cannot be output. An example of a binary signal and an output signal corresponding to the binary signal which is output from the digital filters illustrated in FIG. 6 is as follows:
Binary signal: −1 −1 −1 −1 +1 +1 −1 −1 −1 +1 +1 +1 +1 +1 +1
Output signal: −4 −4 −2 +2 +2 −2 −4 −2 +2 +4 +4 +4 +4

FIG. 7 is a graph illustrating an output signal when a binary signal is changed from −1 to 1. In FIG. 7, a dotted line represents the binary signal and a solid line represents the output signal. The response characteristics of the binary signal when the binary signal is changed from −1 to 1 correspond to a step response. That is, the output signal does not directly change as the binary signal changes, and the output signal has response characteristics corresponding to a length of 3 (because of 3 taps) and a shape determined by tap coefficients.

A variation in the shape of the output signal, which corresponds to the length 3 and is caused by effects of signals before and after the step input signal, as illustrated in FIG. 7, is referred to as inter symbol interference (ISI). ISI is a variable depending on a laser spot shape used in an optical pickup and a pit length of an optical disk. Thus, the length of ISI is exactly proportional to the storage capacity of an optical disk having the same spot shape. To obtain an ideal signal when ISI exists, the distribution of the ideal signal should be analyzed.

To analyze the distribution of the ideal signal, the waveform of an output signal is checked when a 1-bit binary signal which has been changed is input in a PR(1,2,1) channel. When the input signal is changed by 1 bit, the output signal illustrated in FIG. 6 is also changed by 1 bit. In this case, an input signal (which is the output signal illustrated in FIG. 6, represented by the arrow pointing away from the adder) obtained by a circuit is located between the signal represented by the solid line and the signal represented by the dotted line illustrated in FIG. 7. When PRML (Partial Response Maximum Likelihood) is used, signal discrimination is carried out based on whether an input signal is close to the signal corresponding to the solid line and the signal corresponding to the dotted line illustrated in FIG. 7.

The probability that the distribution of an ideal signal has an error decreases as the distance between the signal corresponding to the solid line and the signal corresponding to the dotted line illustrated in FIG. 7 increases. This result is because the basic principle of PRML is to determine whether an input signal is close to the signal corresponding to the solid line or the signal corresponding to the dotted line illustrated in FIG. 7, and it becomes easier to determine whether the input signal is close to the signal corresponding to the solid line and the signal corresponding to the dotted line illustrated in FIG. 7 as the distance between the signal corresponding to the solid line and the signal corresponding to the dotted line illustrated in FIG. 7 increases.

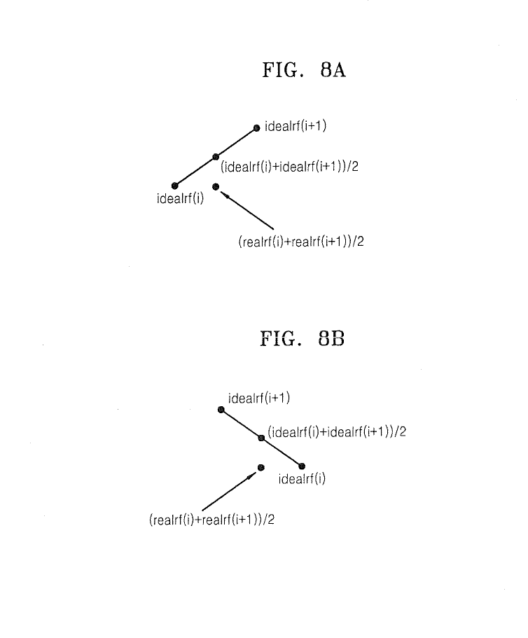

FIGS. 8A and 8B illustrate a method of calculating a time axis error of an input signal according to an embodiment of the present invention. FIG. 8A illustrates the case when a binary signal is changed from 0 to 1 and FIG. 8B illustrates the case when the binary signal is changed from 1 to 0. Referring to FIG. 8A, when an ideal signal at a time i is idealrf(i) and an ideal signal at a time i+1 is idealrf(i+1), a mean of an ideal signal at a time i+0.5 is represented as follows:

$$\frac{idealrf ( i ) + idealrf ( i + 1 )}{2}$$

Here, the time i and the time i+1 respectively represent instants of time when the binary signal changes from 0 to 1. When an input signal at the time i is realrf(i) and an input signal at the time i+1 is realrf(i+1), a mean of the input signal at the time i+0.5 is represented as follows:

$$\frac{realrf ( i ) + realrf ( i + 1 )}{2}$$

When a difference between the mean of the ideal signal and the mean of the input signal is obtained, a difference between the ideal signal at the instant of time when the binary signal is changed from 0 to 1 and the actual input signal is acquired. When the difference between the ideal signal at the instant of time when the binary signal is changed from 0 to 1 and the actual input signal is divided by a variation in the ideal signal, the time axis error of the input signal is obtained. This process is mathematically represented as follows:

$$\frac{\begin{matrix}\frac{idealrf ( i ) - idealrf ( i + 1 )}{2} - \\ \frac{realrf ( i ) + realrf ( i + 1 )}{2}\end{matrix}}{idealrf ( i + 1 ) - idealrf ( i )} \qquad [ Equation 2 ]$$

FIG. 8B illustrates a method of calculating a time axis error of the input signal when the binary signal is changed from 1 to 0. In this case, the time axis error is calculated using Equation 2. The calculated time axis error corresponds to a jitter.

FIG. 9 is a graph illustrating the frequency of a time axis error detected through the jitter measuring apparatus shown in FIG. 3. Referring to FIG. 9, the frequency at which the time axis error becomes 0 corresponds to approximately 67000 cycles over the whole input signal. Thus, the jitter measuring apparatus shown in FIG. 3 accurately measures jitter, and generates a graph, such as the graph illustrated in FIG. 9, to be used as a signal quality evaluation index.

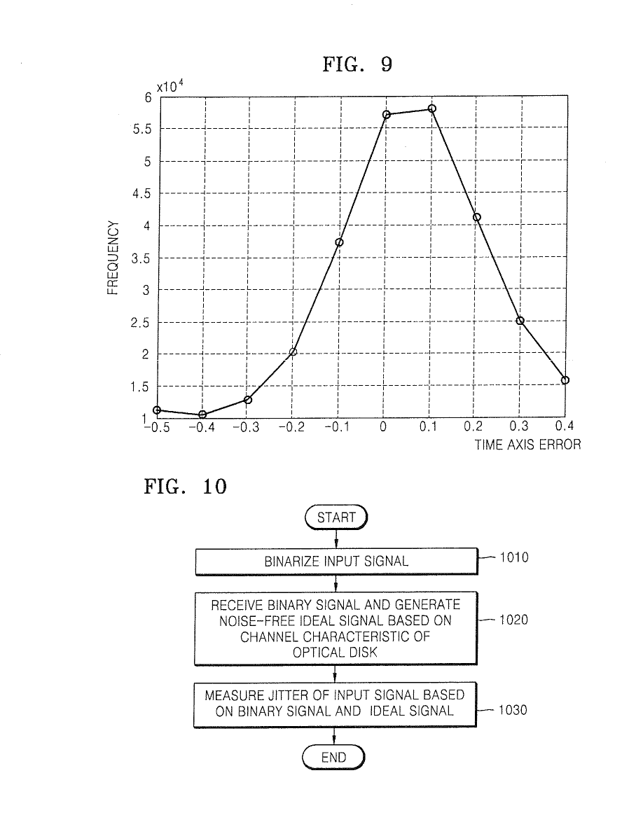

FIG. 10 is a flow chart of a jitter measuring method according to an embodiment of the present invention. Referring to FIG. 10, an input signal is binarized in operation 1010. The input signal is an RF signal picked up from an optical disk and has properties of an analog signal due to characteristics of the optical disk and the optical disk player. Accordingly, the input signal is converted into a binary signal. The input signal can be binarized using various methods, such as, for example, a method using a slicing circuit including a comparator and a low pass filter, or a method using a viterbi decoder such as the PMRL method.

The binary signal obtained by binarizing the input signal is received and a noise-free ideal signal is generated based on the channel characteristics of the optical signal in operation 1020. The ideal signal is generated by filtering the binary signal using the channel characteristics of the optical disk. Furthermore, the ideal signal is generated through a method which uses a level representing the characteristics of the input signal. The level is previously set or detected from the input signal by an additional device, such as, for example, the level detector 410. The jitter of the input signal is accurately measured based on the binary signal and the ideal signal in operation 1030.

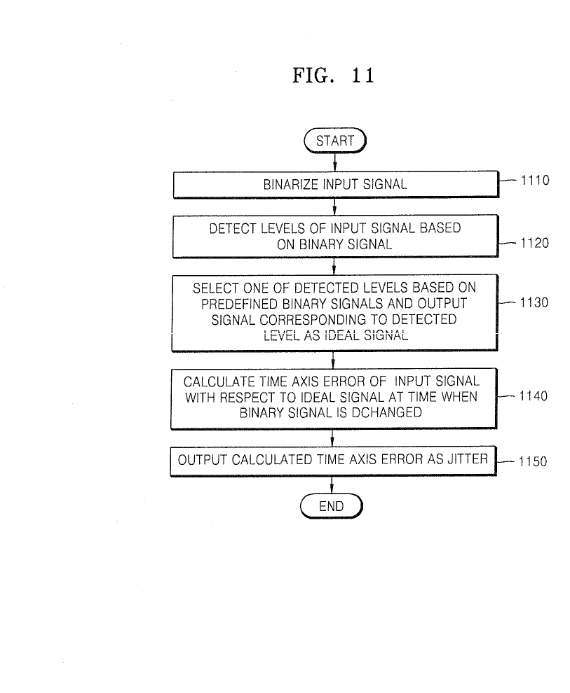

FIG. 11 is a flow chart of a jitter measuring method according to another embodiment of the present invention. Referring to FIG. 11, an input signal is binarized to generate a binary signal in operation 1110. Levels of the input signal are detected based on the generated binary signal in operation 1120. To detect the levels of the input signal, the input signal is split into a plurality of levels using the binary signal, and then means of the respective levels are obtained using mean filters respectively corresponding to the levels. The means of the levels are output as the detected levels.

One of the detected levels is selected based on a plurality of predefined binary signals and a signal corresponding to the selected level is output as an ideal signal in operation 1130. The predefined binary signals are obtained by passing the binary signal through a plurality of delay units and synchronizing binary signals respectively output from the delay units. One of the detected levels is selected based on signals which are obtained by multiplexing the binary signals.

A time axis error of the input signal with respect to the ideal signal at the time when the binary signal is changed is calculated in operation 1140. The time axis error is calculated using Equation 2. The calculated time axis error is output as jitter in operation 1150.

FIG. 12 is a block diagram of an optical disk player 1200 according to an embodiment of the present invention. Referring to FIG. 12, the optical disk player 1200 reproduces data from an optical disk 1205 and includes a pick-up 1210, a signal converter 1220, an amplifier 1230, an equalizer 1240, a jitter measuring device 1250 and a signal processor 1260. The optical disk player 1200 may also record data to the optical disk 1205. Furthermore, the optical disk player 1200 may include a variety of other components, such as additional lenses, etc.

The pick-up 1210 irradiates a laser beam onto the surface of an optical disk 1205 and picks up a signal reflected from the surface of the optical disk 1205 to reproduce data. The signal converter 1220 converts the picked up signal into an RF signal and the amplifier 1230 amplifies the RF signal. The equalizer 1240 filters the RF signal.

The RF signal output from the equalizer 1240 is input to the jitter measuring device 1250. The jitter measuring device 1250 includes the binarization unit 310, the ideal signal generator 320, and the jitter measurement unit 330, as shown in FIG. 3 and described above. The binarization unit 310 converts the RF signal into a binary signal to compensate for the analog characteristics of the RF signal which are created due to the characteristics of the optical disk 1205 and the characteristics of the optical disk player 1200. The ideal signal generator 320 receives the binary signal transmitted from the binarization unit 310 and generates a noise-free ideal signal based on the channel characteristics of the optical disk 1205. The ideal signal generator 320 generates the ideal signal by filtering the binary signal using the channel characteristics of the optical disk or by using a level representing the characteristics of the input signal. Then, the jitter measurement unit 330 accurately measures jitter of the input RF signal based on the binary signal output from the binarization unit 310 and the ideal signal output from the ideal signal generator 320.

The signal processor 1260 detects the quality of the input RF signal based on the period of the RF signal which is measured by the equalizer 1240 and the jitter measuring device 1250. Then, the signal processor 1260 performs demodulation and error correction on the RF signal to generate digital data, such as audio files, video files, text files, etc.

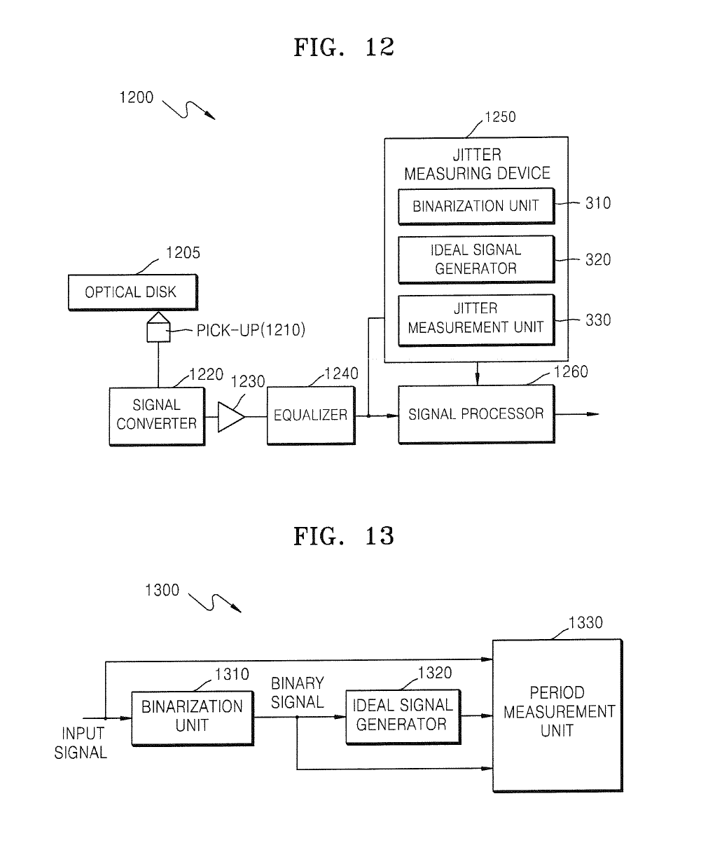

FIG. 13 is a block diagram of a signal period measuring apparatus 1300 according to an embodiment of the present invention. Referring to FIG. 13, the signal period measuring apparatus 1300 includes a binarization unit 1310, an ideal signal generator 1320 and a period measurement unit 1330. The signal period measuring apparatus 1300 may be included in an optical disk player, such as, for example, the optical disk player 1200, or may be manufactured and sold separately from the optical disk player 1200.

The binarization unit 1310 performs substantially the same functions as the functions performed by the binarization unit 310 illustrated in FIG. 3. Specifically, the binarization unit 1310 converts an input RF signal into a binary signal. As described above, when a binary signal is recorded on the surface of an optical disk, for example, the optical disk 1205, an RF signal picked up from the optical disk 1205 has properties of an analog signal due to the characteristics of the optical disk and characteristics of the optical disk player. Accordingly, the input RF signal is converted into the binary signal by the binarization unit 1310. The binarization unit 1310 can generate the binary signal using a variety of methods, such as by using a slicing circuit and the method as illustrated in FIG. 1. Alternatively, the binarization unit 1310 can generate the binary signal using a method which employs a viterbi decoder, such as the PRML method.

The ideal signal generator 1320 receives the binary signal transmitted from the binarization unit 1310 and generates a noise-free ideal signal based on the channel characteristics of an optical disk, for example, the optical disk 1205, from which the input RF signal is read. According to an aspect of the present invention, the ideal signal is generated by filtering the binary signal using the channel characteristics of the optical disk 1205.

The ideal signal generator 1320 generates the ideal signal using a level representing the characteristics of the input signal. Specifically, a level representing the channel characteristics of the optical disk 1205 is selected based on a plurality of predefined binary signals. After the level is selected, the ideal signal generator 1320 outputs a signal corresponding to the selected level. The predefined binary signals are obtained by passing the binary signal input to the ideal signal generator 1320 through a plurality of delay units, such as the binary delay units 415_1 to 415_{—}k (FIG. 5), and synchronizing binary signals respectively output from the delay units. The level representing the channel characteristics of the optical disk 1205 is selected from signals obtained by multiplexing the binary signals. To select the level, the input signal is divided into a plurality of levels.

Finally, the period measurement unit 1330 accurately measures the period of the input RF signal based on the binary signal output from the binarization unit 1310 and the ideal signal output from the ideal signal generator 1320.

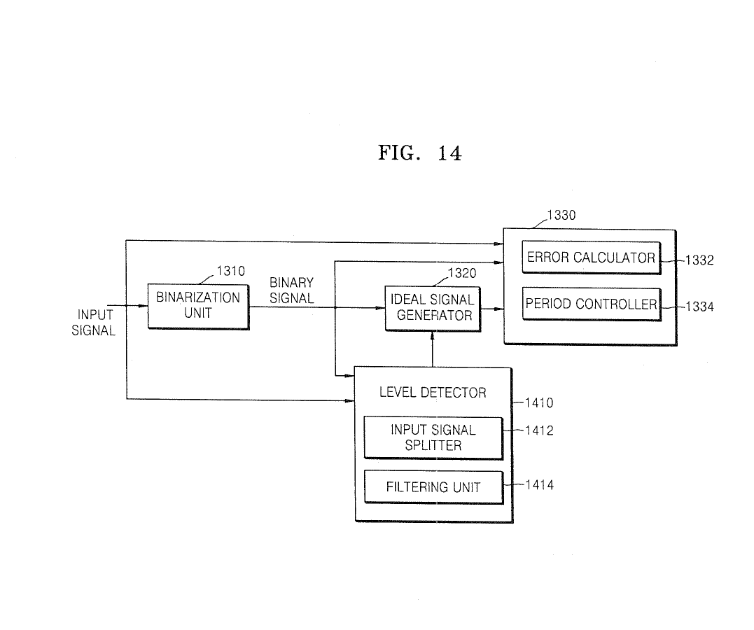

FIG. 14 is a block diagram illustrating a detailed configuration of the signal period measuring apparatus 1300 illustrated in FIG. 13. Referring to FIG. 14, the signal period measuring apparatus 1300 includes the binarization unit 1310, the ideal signal generator 1320, a level detector 1410 and the period measurement unit 1330. The level detector 1410 includes an input signal splitter 1412 and a filtering unit 1414. The period measurement unit 1330 includes an error calculator 1332 and a period controller 1334.

The binarization unit 1310 binarizes an input signal read from an optical disk, such as the optical disk 1205 (FIG. 12), and outputs a binary signal. The ideal signal generator 1320 receives the binary signal transmitted from the binarization unit 1310 and generates a noise-free ideal signal based on the channel characteristics of the optical disk 1205 from which the input signal is picked up. The ideal signal generator 1320 selects a level corresponding to the channel characteristics of the optical disk 1205 from a predetermined plurality of binary signals and outputs a signal having the selected level as the ideal signal. To perform this process, the input signal is divided into a plurality of levels, and values or signals respectively corresponding to the levels are set.

The level detector 1410 detects the level of the input signal based on the binary signal. The input signal splitter 1412 splits the input signal into a plurality of levels using the binary signal. The filtering unit 1414 includes mean filters (not shown) and obtains means of the respective levels using the mean filters. According to an aspect of the present invention, the level detector 1410 has the same configuration and performs the same functions as the functions performed by the level detector 410 illustrated in FIG. 5.

The period measurement unit 1330 accurately measures the period of the input signal based on the binary signal and the ideal signal. The input signal is synchronized by a delay unit and then input to the period measurement unit 1330. The quality of the input signal is accurately determined when the period of the input signal is accurately measured. The error calculator 1332 of the period measurement unit 1330 calculates a time axis error of the input signal with respect to the ideal signal at a time when the binary signal is changed. The period controller 1334 adds the time axis error calculated by the error calculator 1332 to the period of the input signal right before the binary signal is changed, and then subtracts the time axis error from the period of the input signal right after the binary signal is changed to control the period of the input signal.

For example, the period of the input signal is controlled using Equation 2 when the binary signal is changed from 0 to 1, as illustrated in FIG. 8A. Assume that the time when the binary signal is changed from 0 to 1 corresponds to 5T and 4T. Here, T corresponds to a mark length on a time axis of the input signal, which includes marks and spaces, that is, a period. The period of the input signal is controlled in a manner such that the time axis error is added to 5T and the time axis error is subtracted from 4T.

A method of calculating the time axis error at the time when the binary signal is changed from 1 to 0 is illustrated in FIG. 8B. In this case, the time axis error is calculated using Equation 2 and the period of the input signal is controlled by adding the time axis error to the period right before the binary signal is changed, and subtracting the time axis error from the period right after the binary signal is changed.

FIG. 15 is a graph illustrating the relationship between a signal magnitude and a mark length which is calculated using the signal period measuring apparatus 1300 shown in FIG. 13. As the recording density of an optical disk increases, such as, for example, when DVDs are replaced by HD-DVDs or BDs, the magnitude of an input signal with a short period decreases so that jitter of the input signal is difficult to measure. However, the apparatuses and methods according to aspects of the present invention enable a user to accurately measure the period of the input signal to thereby obtain a graph, such as the graph illustrated in FIG. 15. In FIG. 15, the horizontal axis represents ten times the mark length of the optical disk 1205, and the vertical axis represents the magnitude of the input signal read from the optical disk 1205.

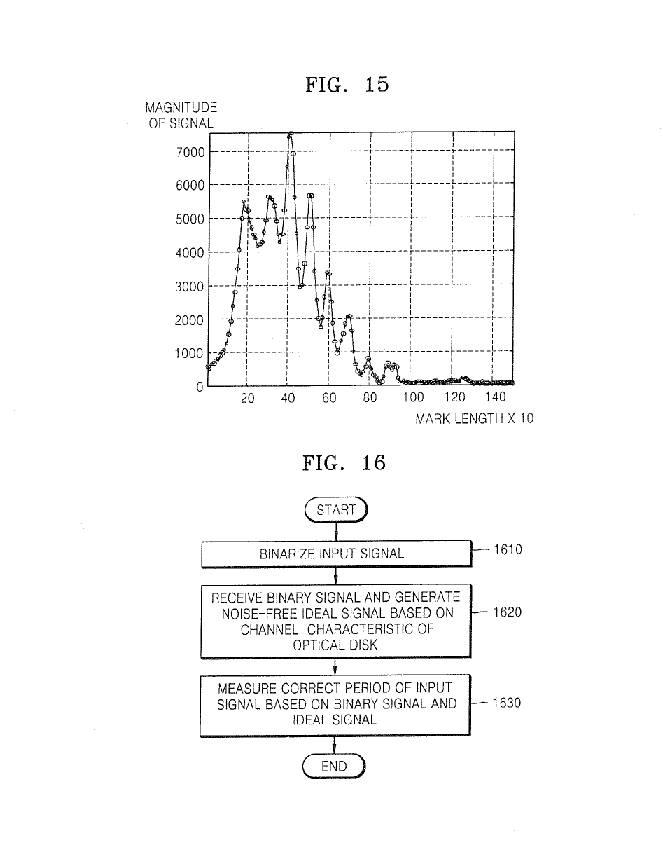

FIG. 16 is a flow chart of a signal period measuring method according to an embodiment of the present invention. Referring to FIG. 16, an input signal is binarized in operation 1610. The input signal is an RF signal picked up from an optical disk 1205 and has properties of an analog signal due to the characteristics of the optical disk 1205 and characteristics of the optical disk player which reproduces data from the optical disk 1205, such as the optical disk player 1200 shown in FIG. 12. Accordingly, the input signal should be converted into a binary signal. As described above, the input signal can be binarized using a method which employs a slicing circuit including a comparator and a filter, such as a low pass filter. Alternatively, the input signal can binarized using a method which employs a viterbi decoder, such as the PMRL method.

The binary signal obtained by binarizing the input signal is received and a noise-free ideal signal is generated based on the channel characteristics of the optical signal in operation 1620. The ideal signal is generated by filtering the binary signal using the channel characteristics of the optical disk 1205. Furthermore, the ideal signal is generated by using a method which employs a level representing the characteristics of the input signal. The level may be previously set, or may be detected from the input signal by using an additional device.

Finally, the period of the input signal is accurately measured based on the binary signal and the ideal signal in operation 1630. Although not limited thereto, operation 1630 may measure the period of the input signal using a method which is substantially the same as the method discussed above with reference to the period measurement unit 1330 shown in FIG. 13.

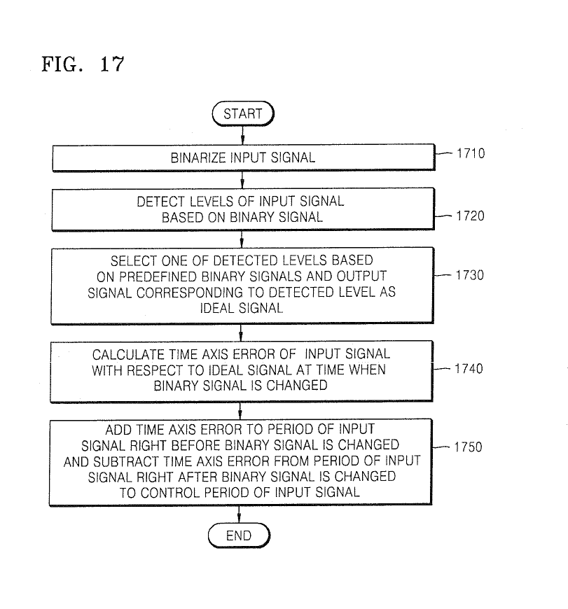

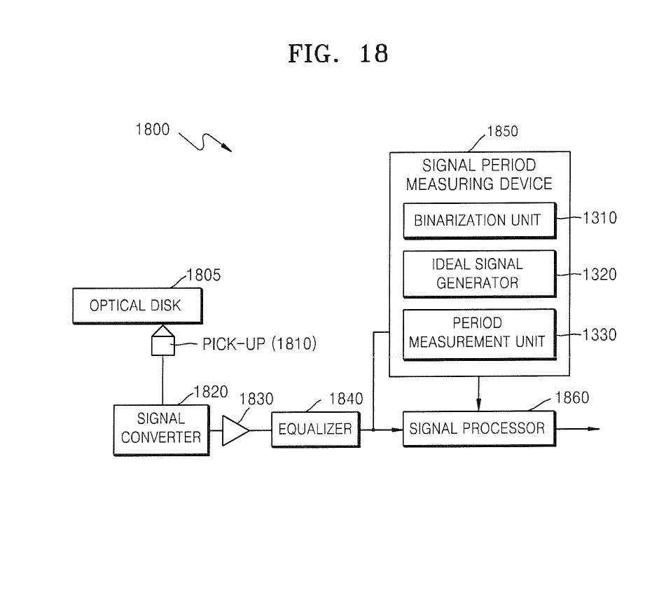

FIG. 17 is a flow chart of a signal period measuring method according to another embodiment of the present invention. Referring to FIG. 17, an input signal is binarized to generate a binary signal in operation 1710. Levels of the input signal are detected based on the binary signal in operation 1720. To detect the levels of the input signal, the input signal is split into a plurality of levels using the binary signal. Then, means of the respective levels are obtained using mean filters respectively corresponding to the levels. The means of the levels are output as the detected levels.

One of the detected levels is selected based on a plurality of predefined binary signals and a signal corresponding to the selected level is output as an ideal signal in operation 1730. The predefined binary signals are obtained by passing the binary signal through a plurality of delay units and synchronizing binary signals respectively output from the delay units. One of the detected levels is selected based on signals obtained by multiplexing the binary signals.

A time axis error of the input signal with respect to the ideal signal at the time when the binary signal is changed is calculated in operation 1740. According to an aspect of the invention, the time axis error is calculated using Equation 2. However, it is understood that other equations instead of Equation 2 may instead be used to calculate the time axis error.

When Equation 2 is used, the period of the input signal is controlled by adding the time axis error to the period of the input signal right before the binary signal is changed and subtracting the time axis error from the period of the input signal right after the binary signal is changed in operation 1750. Assume that the time when the binary signal is changed from 0 to 1 corresponds to 5T and 4T. Here, T corresponds to a mark length on a time axis of the input signal, which includes marks and spaces, that is, a period. The period of the input signal is controlled in a manner that the time axis error is added to 5T and the time axis error is subtracted from 4T.

FIG. 18 is a block diagram of an optical disk player 1800 according to another embodiment of the present invention. Referring to FIG. 18, the optical disk player 1800 includes a pick-up 1810, a signal converter 1820, an amplifier 1830, an equalizer 1840, a signal period measuring device 1850 and a signal processor 1860. It is understood that the optical disk player 1800 may have other components in addition to those shown in FIG. 18 and described below, such as lenses, additional amplifiers, etc.

The pick-up 1810 irradiates a laser beam onto the surface of an optical disk 1805 and picks up a signal reflected from the surface of the optical disk 1805. The signal converter 1820 converts the picked up signal into an RF signal and the amplifier 1830 amplifies the RF signal. The equalizer 1840 filters the RF signal.

The RF signal output from the equalizer 1840 is input to the signal period measuring device 1850. The signal period measuring device 1850 includes a binarization unit 1310, an ideal signal generator 1320, and a period measurement unit 1330. The binarization unit 1310 converts the RF signal into a binary signal because the RF signal has the properties of an analog signal due to the characteristics of the optical disk 1805 and characteristics of the optical disk player 1800. The ideal signal generator 1320 receives the binary signal and generates a noise-free ideal signal based on the channel characteristics of the optical disk 1805. The ideal signal is generated by filtering the binary signal using the channel characteristics of the optical disk 1805, or by using a level representing the characteristics of the input RF signal. The period measurement unit 1330 measures the correct period of the input RF signal based on the binary signal output from the binarization unit 1310 and the ideal signal output from the ideal signal generator 1320.

The signal processor 1860 checks the quality of the input RF signal based on the period of the RF signal, which is measured by the equalizer 1840 and the signal period measuring device 1850. Then, the signal processor 1860 performs demodulation and error correction on the RF signal to generate digital data, such as audio files, video files, text files, etc.

Aspects of the invention can also be embodied as computer readable codes on a computer readable recording medium. The computer readable recording medium is any data storage device that can store data which can be thereafter read by a computer system. Examples of the computer readable recording medium include read-only memory (ROM), random-access memory (RAM), CD-ROMs, magnetic tapes, floppy disks, optical data storage devices, and a computer data signal embodied in a carrier wave comprising a compression source code segment comprising the code and an encryption source code segment comprising the code (such as data transmission through the Internet). The computer-readable recording medium can also be distributed over network-coupled computer systems so that the computer-readable code is stored and executed in a distributed fashion.

As described above, aspects of the present invention provide a jitter measuring apparatus and method, a signal period measuring apparatus and method, and an optical disk player which each enable a user to measure jitter of an input RF signal more accurately than conventional apparatuses and methods. According to aspects of the present invention, the quality of a signal is correctly determined based on a measured jitter and period of the signal.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. An apparatus to measure jitter of an input signal read from an optical disk, comprising:
a binarization unit to binarize the input signal to generate a binary signal;
an ideal signal generator to generate a noise-free ideal signal based on channel characteristics of the optical disk; and
a jitter measurement unit to measure the jitter of the input signal based on the binary signal and the noise-free ideal signal.

2. The apparatus of claim 1, wherein the ideal signal generator generates the noise-free ideal signal by filtering the binary signal using the channel characteristics of the optical disk.

3. The apparatus of claim 1, wherein the ideal signal generator selects a level representing the channel characteristics of the optical disk based on a plurality of predetermined binary signals and outputs a signal corresponding to the selected level as the noise-free ideal signal.

4. The apparatus of claim 1, further comprising a level detector to detect levels of the input signal based on the binary signal, wherein the ideal signal generator selects one of the levels detected by the level detector based on predetermined binary signals and outputs a signal corresponding to the selected level as the noise-free ideal signal.

5. The apparatus of claim 4, wherein the level detector obtains means of the input signal and previous input signals to detect the levels of the input signal.

6. The apparatus of claim 4, wherein the level detector comprises:
an input signal splitter to split the input signal into the levels using the binary signal; and
a filtering unit to obtain means of the respective levels.

7. The apparatus of claim 6, wherein the input signal splitter comprises at least one delay unit to delay the input signal to synchronize the input signal with the binary signal.

8. The apparatus of claim 1, wherein the jitter measurement unit calculates a time axis error of the input signal with respect to the noise-free ideal signal at a moment when the binary signal changes and outputs the time axis error as the jitter of the input signal.

9. The apparatus of claim 8, wherein the time axis error corresponds to a value obtained by subtracting a mean of the input signal at the moment when the binary signal changes from a mean of the noise-free ideal signal at the moment when the binary signal changes and dividing a subtraction result by a variation of the noise-free ideal signal at the moment when the binary signal changes.

10. The apparatus of claim 7, wherein the input signal splitter further comprises at least one binary delay unit to delay the binary signal to synchronize the input signal with the binary signal.

11. The apparatus of claim 10, wherein the filtering unit comprises at least one low-pass filter to filter the delayed input signal and obtain the means of the respective levels.

12. The apparatus of claim 11, wherein the input signal splitter further comprises:
a select signal generator to combine a plurality of the delayed binary signals input thereto from the at least one binary delay unit and output a select signal; and
a selector to select one of the levels corresponding to the synchronized input signal based on the select signal output from the select signal generator.

13. A method of measuring jitter of an input signal read from an optical disk, comprising:
binarizing the input signal to generate a binary signal;
generating a noise-free ideal signal based on channel characteristics of the optical disk; and
measuring the jitter of the input signal based on the binary signal and the noise-free ideal signal.

14. The method of claim 13, wherein the generating of the noise-free ideal signal comprises generating the noise-free ideal signal by filtering the binary signal using the channel characteristics of the optical disk.

15. The method of claim 13, wherein the generating of the noise-free ideal signal comprises selecting a level representing the channel characteristics of the optical disk based on a plurality of predetermined binary signals and outputting a signal corresponding to the selected level as the noise-free ideal signal.

16. The method of claim 13, further comprising detecting levels of the input signal based on the binary signal, wherein the generating of the noise-free ideal signal comprises:
selecting one of the levels detected by the level detector based on predetermined binary signals; and
outputting a signal corresponding to the selected level as the noise-free ideal signal.

17. The method of claim 16, wherein the detecting of the levels of the input signal comprises obtaining means of the input signal and previous input signals to detect the levels of the input signal.

18. The method of claim 16, wherein the detecting of the levels of the input signal comprises:
splitting the input signal into a plurality of levels using the binary signal; and
obtaining means of the respective levels.

19. The method of claim 18, wherein the splitting of the input signal comprises delaying the input signal to synchronize the input signal with the binary signal before the input signal is split into the plurality of levels.

20. The method of claim 13, wherein the measuring of the jitter comprises:
calculating a time axis error of the input signal with respect to the noise-free ideal signal at a moment when the binary signal changes; and
outputting the time axis error as the jitter of the input signal.

21. The method of claim 20, wherein the time axis error corresponds to a value obtained by subtracting a mean of the input signal at the moment when the binary signal changes from a mean of the noise-free ideal signal at the moment when the binary signal changes and dividing the subtraction result by a variation of the noise-free ideal signal at the moment when the binary signal changes.

22. The method of claim 19, further comprising delaying the binary signal to synchronize the input signal with the binary signal.

23. The method of claim 22, wherein the obtaining means of the respective levels comprises low-pass filtering the delayed input signal to obtain the means of the respective levels.

24. The method of claim 23, wherein the splitting of the input signal further comprises:
combining a plurality of the delayed binary signals;
outputting a select signal based on the combining of the plurality of the delayed binary signals; and
selecting one of the levels corresponding to the synchronized input signal based on the output select signal.

25. An optical disk player comprising:
an equalizer to equalize a signal picked up from an optical disk;
a jitter measuring device to receive the signal transmitted from the equalizer and to measure jitter of the signal; and
a signal processor to evaluate a quality of the signal using the measured jitter, wherein the jitter measuring device comprises:
a binarization unit to binarize the signal to generate a binary signal,
an ideal signal generator to generate a noise-free ideal signal based on channel characteristics of the optical disk, and
a jitter measurement unit to measure the jitter of the signal based on the binary signal and the noise-free ideal signal.

26. A computer readable recording medium encoded with a computer-readable program with processing instructions for executing a jitter measuring method, the jitter measuring method comprising:
binarizing an input signal to generate a binary signal;
generating a noise-free ideal signal based on channel characteristics of an optical disk from which the input signal is read; and
measuring the jitter of the input signal based on the binary signal and the noise-free ideal signal.

27. An apparatus to measure a period of an input signal picked up from an optical disk, comprising:
a binarization unit to binarize the input signal to generate a binary signal;
an ideal signal generator to generate a noise-free ideal signal based on channel characteristics of the optical disk; and
a period measurement unit to measure the period of the input signal based on the binary signal and the noise-free ideal signal.

28. The apparatus of claim 27, wherein the ideal signal generator generates the noise-free ideal signal by filtering the binary signal using the channel characteristics of the optical disk.

29. The apparatus of claim 27, wherein the ideal signal generator selects a level representing the channel characteristics of the optical disk based on a plurality of predetermined binary signals and outputs a signal corresponding to the selected level as the noise-free ideal signal.

30. The apparatus of claim 27, further comprising a level detector to detect levels of the input signal based on the binary signal, wherein the ideal signal generator selects one of the levels detected by the level detector based on predetermined binary signals and outputs a signal corresponding to the selected level as the noise-free ideal signal.

31. The apparatus of claim 30, wherein the level detector obtains means of the input signal and previous input signals to detect the levels of the input signal.

32. The apparatus of claim 30, wherein the level detector comprises:
an input signal splitter to split the input signal into a plurality of the levels using the binary signal; and
a filtering unit to obtain means of the respective levels.

33. The apparatus of claim 32, wherein the input signal splitter comprises at least one delay unit to delay the input signal to synchronize the input signal with the binary signal.

34. The apparatus of claim 27, wherein the period measurement unit comprises:
an error calculator to calculate a time axis error of the input signal with respect to the noise-free ideal signal at a moment when the binary signal changes; and
a period controller to add the time axis error to the period of the input signal right before the binary signal changes and to subtract the time axis error from the period of the input signal right after the binary signal changes to control the period of the input signal.

35. The apparatus of claim 34, wherein the error calculator subtracts a mean of the input signal at the moment when the binary signal changes from a mean of the noise-free ideal signal at the moment when the binary signal changes and divides a subtraction result by a variation of the noise-free ideal signal at the moment when the binary signal changes to calculate the time axis error.

36. The apparatus of claim 33, wherein the input signal splitter further comprises at least one binary delay unit to delay the binary signal to synchronize the input signal with the binary signal.

37. The apparatus of claim 36, wherein the filtering unit comprises at least one low-pass filter to filter the delayed input signal and obtain the means of the respective levels.

38. The apparatus of claim 37, wherein the input signal splitter further comprises:
a select signal generator to combine a plurality of the delayed binary signals input thereto from the at least one binary delay unit and output a select signal; and
a selector to select one of the levels corresponding to the synchronized input signal based on the select signal output from the select signal generator.

39. A method of measuring the period of an input signal read from an optical disk, comprising:
binarizing the input signal to generate a binary signal;
generating a noise-free ideal signal based on channel characteristics of the optical disk; and
measuring the period of the input signal based on the binary signal and the noise-free ideal signal.

40. The method of claim 39, wherein the generating of the noise-free ideal signal comprises generating the noise-free ideal signal by filtering the binary signal using the channel characteristics of the optical disk.

41. The method of claim 39, wherein the generating of the noise-free ideal signal comprises:
selecting a level representing the channel characteristics of the optical disk based on a plurality of predetermined binary signals; and
outputting a signal corresponding to the selected level as the noise-free ideal signal.

42. The method of claim 39, further comprising detecting levels of the input signal based on the binary signal, wherein the generating of the noise-free ideal signal comprises:
selecting one of the levels detected by the level detector based on predetermined binary signals; and
outputting a signal corresponding to the selected level as the noise-free ideal signal.

43. The method of claim 42, wherein the detecting of the levels of the input signal comprises obtaining means of the input signal and previous input signals to detect the levels of the input signal.

44. The method of claim 42, wherein the detecting of the levels of the input signal comprises:
splitting the input signal into the levels using the binary signal; and
obtaining means of the respective levels.

45. The method of claim 44, wherein the splitting of the input signal comprises delaying the input signal to synchronize the input signal with the binary signal before the input signal is split into the levels.

46. The method of claim 39, wherein the measuring of the period comprises:
calculating a time axis error of the input signal with respect to the noise-free ideal signal at a moment when the binary signal changes;
adding the time axis error to the period of the input signal right before the moment when the binary signal changes; and
subtracting the time axis error from the period of the input signal right after the moment when the binary signal changes to control the period of the input signal.

47. The method of claim 46, wherein the calculating of the time axis error comprises:
subtracting a mean of the input signal at the moment when the binary signal changes from a mean of the noise-free ideal signal at the moment when the binary signal changes; and
dividing a result of the subtracting by a variation of the noise-free ideal signal at the moment when the binary signal changes to calculate the time axis error.

48. The method of claim 45, further comprising delaying the binary signal Lo synchronize the input signal with the binary signal.

49. The method of claim 48, wherein the obtaining means of the respective levels comprises low-pass filtering the delayed input signal to obtain the means of the respective levels.

50. The method of claim 49, wherein the splitting of the input signal further comprises:
combining a plurality of the delayed binary signals;
outputting a select signal based on the combining of the plurality of the delayed binary signals; and
selecting one of the levels corresponding to the synchronized input signal based on the output select signal.

51. An optical display player comprising:
an equalizer to equalize a signal picked up from an optical disk;
a signal period measuring device to measure the period of the signal; and
a signal processor to evaluate the quality of the signal using the measured period,
wherein the signal period measuring device comprises:
a binarization unit to binarize the signal to generate a binary signal,
an ideal signal generator to generate a noise-free ideal signal based on channel characteristics of the optical disk, and
a period measurement unit to measure jitter of the input signal based on the binary signal and the noise-free ideal signal.

52. A computer readable recording medium encoded with a computer readable program with processing instructions for executing a signal period measuring method, the signal period measuring method comprising:
binarizing an input signal to generate a binary signal;
generating a noise-free ideal signal based on channel characteristics of an optical disk from which the input signal is picked up; and
measuring a period of the input signal based on the binary signal and the noise-free ideal signal.
